(19) United States
(12) Patent Application Publication
(10) Pub. No.: US 2025/0324866 A1
(43) Pub. Date: Oct. 16, 2025

(54) DISPLAY MODULE AND DISPLAY DEVICE INCLUDING THE SAME

(71) Applicant: Samsung Display Co., Ltd., Yongin-si (KR)

(72) Inventors: SEUNGYEON JEONG, Yongin-si (KR); OHJEONG KWON, Yongin-si (KR); HYEOJI KANG, Yongin-si (KR); Hyebeom SHIN, Yongin-si (KR); HONGYEON LEE, Yongin-si (KR)

(73) Assignee: Samsung Display Co., Ltd., Yongin-si (KR)

(21) Appl. No.: 18/928,812

(22) Filed: Oct. 28, 2024

(30) Foreign Application Priority Data
Apr. 15, 2024 (KR) 10-2024-0049919

(51) Int. Cl. H10K 59/126; H10K 59/38; H10K 59/80; H10K 102/00

(52) U.S. Cl. CPC H10K 59/126; H10K 59/38; H10K 59/879; H10K 59/8791; H10K 2102/351

(57) ABSTRACT

A display module including a substrate which may include multiple pixel areas, a driving circuit layer disposed on the substrate, a light emitting layer disposed on the driving circuit layer and extending continuously across the pixel areas, multiple color filters disposed on the light emitting layer that overlap the pixel areas, respectively, a light blocking pattern disposed between the color filters and including a metal material having a multilayer structure, a phase retardation plate disposed on the color filters that retards a phase of incident light, and a wire grid polarizer including multiple metal patterns spaced apart from each other by a distance from each other.

### CROSS-REFERENCE TO RELATED APPLICATION(S)

This application claims priority under 35 U.S.C. § 119 to and benefits of Korean Patent Application No. 10-2024-0049919 filed on Apr. 15, 2024 in the Korean Intellectual Property Office, the entire contents of which are incorporated herein by reference.

### BACKGROUND

### 1. Technical Field

The disclosure relates to a display module including a light blocking pattern and a display device including the same.

### 2. Description of the Related Art

Electronic apparatuses such as smartphones, notebook computers, navigation devices, and smart televisions, which provide images for users, include display devices for displaying the images. Augmented reality devices, virtual reality devices, and video projection devices may include micro display devices. The micro display devices may include CMOS wafers and light emitting diodes disposed on the CMOS wafers in order to be driven at low power and also display images having high luminance.

### SUMMARY

The disclosure provides a display module in which color mixture is prevented and which has improved light efficiency, and a display device including the display module.

An embodiment of the disclosure may provide a display module including a substrate which includes a plurality of pixel areas, a driving circuit layer disposed on the substrate, a light emitting layer disposed on the driving circuit layer and extends continuously across the pixel areas, a plurality of color filters which are disposed on the light emitting layer and overlap the plurality of pixel areas, respectively, a light blocking pattern disposed between the plurality of color filters and includes a metal material having a multilayer structure, a phase retardation plate disposed on the plurality of color filters to retard a phase of incident light, and a wire grid polarizer disposed on the phase retardation plate and including a plurality of metal patterns spaced apart from each other by a distance (e.g., predetermined or selectable distance) from each other.

In an embodiment of the disclosure, the light blocking pattern may include a first metal layer, a second metal layer disposed on the first metal layer, and a third metal layer disposed on the second metal layer.

In an embodiment of the disclosure, among the first, second, and third metal layers, the third metal layer may be disposed closest to the phase retardation plate, and a thickness of the third metal layer may be about 150 angstroms or less.

In an embodiment of the disclosure, a thickness of the second metal layer may be about 1000 angstroms or more.

In an embodiment of the disclosure, a reflectance of the second metal layer may be about 80% or more.

In an embodiment of the disclosure, a light transmittance of the second metal layer may be about 0%.

In an embodiment of the disclosure, the first metal layer may include at least one of titanium, molybdenum, or molybdenum-tantalum oxide (MoTaO).

In an embodiment of the disclosure, the second metal layer may include aluminum.

In an embodiment of the disclosure, the third metal layer may include titanium.

In an embodiment of the disclosure, the phase retardation plate may include a λ/4 phase retardation plate.

In an embodiment of the disclosure, the light emitting layer may include a light emitting material that emits white light.

In an embodiment of the disclosure, the display module according to an embodiment of the disclosure may further include a cover window disposed on the wire grid polarizer.

In an embodiment of the disclosure, the display module according to an embodiment of the disclosure may further include a planarization layer that covers the plurality of color filters and the light blocking pattern, the planarization layer may include a substantially flat upper surface.

In an embodiment of the disclosure, the phase retardation plate may be disposed closer to the light blocking pattern than the wire grid polarizer.

In an embodiment of the disclosure, a minimum width of the light blocking pattern on a cross-section may be about 5 micrometers or less.

In an embodiment of the disclosure, a display device may include an ocular lens and a display module accommodation part that provides an image to the ocular lens. The display module accommodation part may include a substrate which includes a plurality of pixel areas, a driving circuit layer disposed on the substrate, a light emitting layer disposed on the driving circuit layer and extends continuously across the plurality of pixel areas, a plurality of color filters which are disposed on the light emitting layer and overlap the plurality of pixel areas, respectively, a light blocking pattern disposed between the plurality of color filters and includes a metal material, a phase retardation plate disposed on the plurality of color filters to retard a phase of incident light, and a wire grid polarizer disposed on the phase retardation plate and including a plurality of metal patterns spaced apart by a distance (e.g., a predetermined or selectable distance) from each other.

In an embodiment of the disclosure, the light blocking pattern may include a first metal layer, a second metal layer disposed on the first metal layer, and a third metal layer disposed on the second metal layer.

In an embodiment of the disclosure, among the first, second, and third metal layers, the third metal layer may be disposed closest to the phase retardation plate, and a thickness of the third metal layer may be about 150 angstroms or less.

In an embodiment of the disclosure, a reflectance of the second metal layer may be about 80% or more.

In an embodiment of the disclosure, a light transmittance of the second metal layer may be about 0%.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a schematic plan view of a display module according to an embodiment of the disclosure;

FIG. 2 is a view illustrating an example of a schematic cross-section of a display device according to an embodiment of the disclosure;

FIG. 3 is a schematic cross-sectional view taken along line I-I′ according to an embodiment of the disclosure;

FIG. 4 is a schematic cross-sectional view for explaining recycled light generated in a display module according to an embodiment of the disclosure;

FIG. 5 is a schematic cross-sectional view for explaining recycled light generated in a display module according to an embodiment of the disclosure;

FIG. 6 is a schematic cross-sectional view of a light emitting layer according to an embodiment of the disclosure;

FIG. 7 is a schematic cross-sectional view of a light blocking pattern according to an embodiment of the disclosure;

FIG. 8 is a graph illustrating reflectance over wavelength for a wire grid polarizer according to an embodiment of the disclosure;

FIG. 9 is a graph illustrating reflectance over wavelength for a light blocking pattern according to an embodiment of the disclosure;

FIG. 10 is a graph illustrating reflectance over thickness for a third metal layer according to an embodiment of the disclosure;

FIGS. 11 and 12 are schematic plan views illustrating a display device according to an embodiment of the disclosure; and

FIGS. 13 and 14 are side views of a display module accommodating part according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc., (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc., may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described with reference to the accompanying drawings.

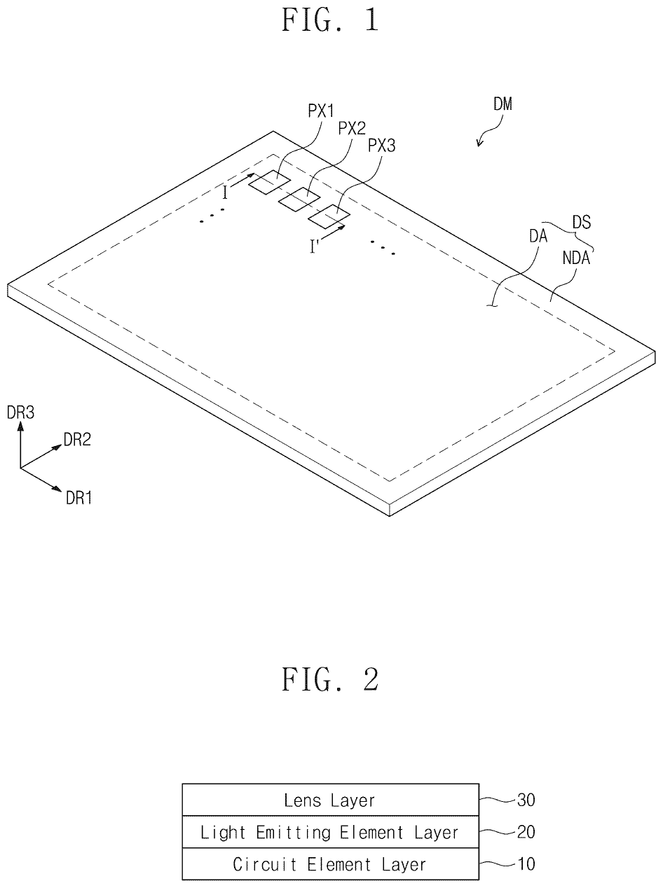

FIG. 1 is a schematic plan view of a display module according to an embodiment of the disclosure.

Referring to FIG. 1, a display module DM according to an embodiment of the disclosure may be parallel to a plane defined by a first direction DR1 and a second direction DR2. The display module DM may have a rectangular shape having long sides extending in the first direction DR1 and short sides extending in the second direction DR2 intersecting the first direction DR1. The display module DM may have a rectangular shape. However, the shape of the display module DM is not limited thereto, and the display module DM may have various shapes. For example, the display module DM may have various shapes such as a circular shape or a polygonal shape.

FIG. 1 and the following drawings illustrate the first direction DR1 to a third direction DR3, and directions indicated by the first direction DR1 to the third direction DR3 used herein may be relative concepts and may be changed to other directions.

In the disclosure, the first direction DR1 and the second direction DR2 may perpendicularly intersect each other, and the third direction DR3 may be normal to a plane defined by the first direction DR1 and the second direction DR2.

A thickness direction of the display module DM may be a direction parallel to the third direction DR3 that is normal to a plane defined by the first direction DR1 and the second direction DR2. In the disclosure, a front surface (or upper surface) and a rear surface (or lower surface) of each of members, which constitute the display module DM, may be defined based on the third direction DR3.

The term “on a plane” used herein may mean in a plan view or a state when viewed on a plane parallel to a plane defined by the first direction DR1 and the second direction DR2. Unless otherwise defined, the term “overlapping” used herein may mean overlapping on a plane.

An upper surface of the display module DM may be defined as a display surface DS, and may have a plane defined by the first direction DR1 and the second direction DR2. An image generated through the display surface DS may be provided for a user.

The display surface DS may include a display area DA and a non-display area NDA around the display area DA. The display area DA displays an image, and the non-display area NDA does not display an image. The non-display area NDA may surround the display area DA, but is not limited thereto. For example, the non-display area NDA may not be disposed at a side (e.g., single side) of the display area DA.

Multiple pixel areas PX1, PX2 and PX3 may be disposed in the display area DA. The pixel areas PX1, PX2 and PX3 may be disposed in a matrix shape. The pixel areas PX1, PX2 and PX3 may each include a pixel circuit and a light emitting diode. All of the pixel areas PX1, PX2 and PX3 may generate light having the same color. In an embodiment of the disclosure, the pixel areas PX1, PX2 and PX3 may include multiple groups that generate light having different colors from each other.

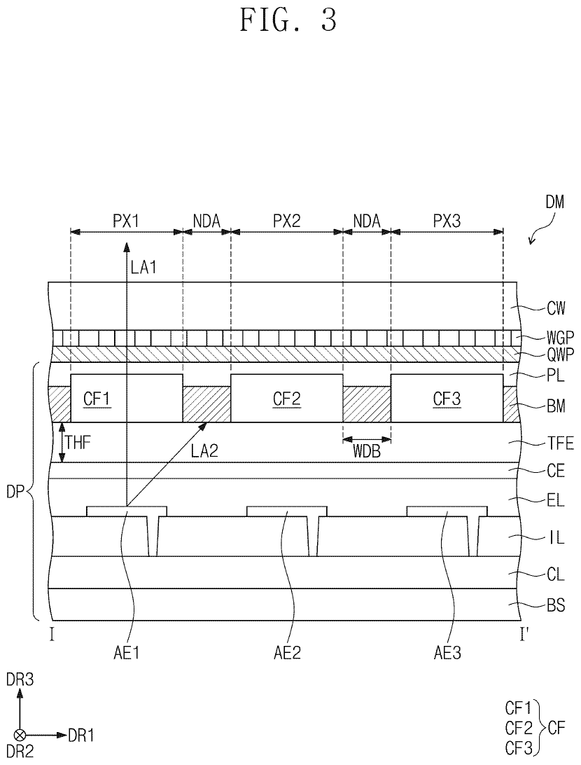

FIG. 2 is a view illustrating an example of a cross-section of a display device according to an embodiment of the disclosure.

Referring to FIG. 2, a display module DM may include a circuit element layer 10, a light emitting element layer 20, and a lens layer 30. However, an embodiment of the disclosure is not limited thereto. For example, in an embodiment of the disclosure, the lens layer 30 may be omitted, or another functional layer may be further added.

The circuit element layer 10 may include a pixel circuit. The pixel circuit may control an operation of a light emitting element of the light emitting element layer 20 to be described later. The pixel circuit may include at least one transistor. The circuit element layer 10 may include a silicon substrate (or substrate).

The light emitting element layer 20 may include light emitting elements disposed to overlap the display area DA (see FIG. 1). The light emitting elements of the light emitting element layer 20 may be electrically connected to driving elements of the circuit element layer 10, and output light through the display area DA (see FIG. 1) in response to signals of the driving elements. For example, the light emitting elements included in the light emitting element layer 20 may include an organic light emitting element, an inorganic light emitting element, a quantum dot light emitting element, a micro-LED light emitting element, or a nano-LED light emitting element. However, an embodiment of the disclosure is not limited thereto, and the light emitting element may include various embodiments of the disclosure as long as light is capable of being generated in response to an electrical signal, or an amount of light may be controllable. The light emitting element according to an embodiment of the disclosure is not limited thereto, and may include various embodiments of the disclosure in which light is capable of being generated in response to an electrical signal or an amount of light may be controllable.

The lens layer 30 may be disposed on the light emitting element layer 20, and include a lens. The lens may be disposed to correspond to a light emitting diode. The lens may collect the light emitted from the light emitting diode. The light collected through the lens may be transmitted through a light guide part.

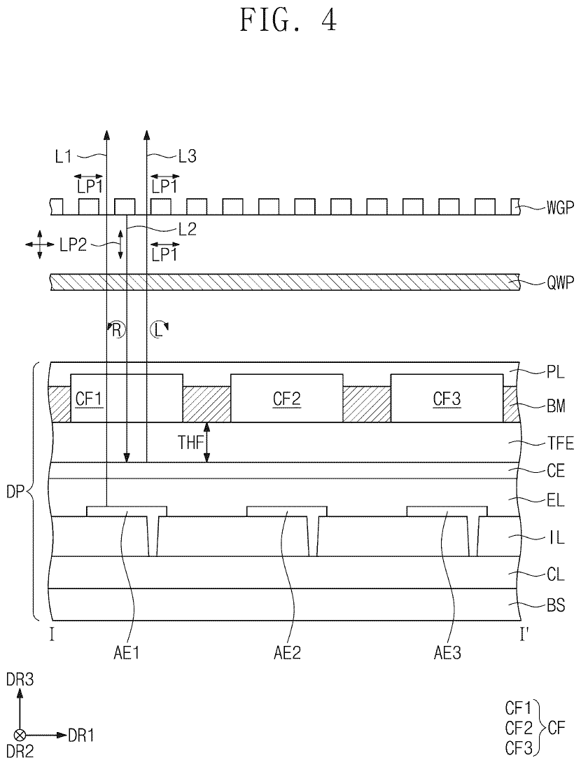

FIG. 3 is a schematic cross-sectional view taken along line I-I′ of FIG. 1 according to an embodiment of the disclosure.

Referring to FIG. 3, a display module DM according to an embodiment of the disclosure may include a display panel DP, a phase retardation plate QWP, a wire grid polarizer WGP, and a cover window CW. Here, the display panel DP may include a silicon substrate (or substrate) BS, a driving circuit layer CL, an insulation layer IL, first to third pixel electrodes AE1, AE2 and AE3, a light emitting layer EL, a common electrode CE, an encapsulating layer TFE, first to third color filters CF1, CF2 and CF3, a light blocking pattern BM, and a planarization layer PL.

As the display module DM may include the first to third pixel areas PX1, PX2 and PX3, the silicon substrate BS may also include the first to third pixel areas PX1, PX2 and PX3. The silicon substrate BS may be a support member for supporting other components of the display module DM. For example, the silicon substrate BS may be a silicon wafer substrate.

The driving circuit layer CL may be disposed on the silicon substrate BS. The driving circuit layer CL may include various driving elements, lines, and the like for driving a light emitting element. For example, the driving circuit layer CL may include various components such as a transistor, a storage capacitor, a gate line, and a data line.

The insulation layer IL may be disposed on the driving circuit layer CL. The insulation layer IL may prevent contact between the first to third pixel electrodes AE1, AE2 and AE3 and the driving circuit layer CL. The insulation layer IL may include an organic material and/or an inorganic material. For example, the insulation layer IL may include an inorganic material such as silicon oxide (SiOₓ), silicon nitride (SiNₓ), or silicon oxynitride (SiOₓN_{y}). However, the material of the insulation layer IL is not limited thereto, and the insulation layer IL may include various materials.

The first to third pixel electrodes AE1, AE2 and AE3 may be disposed on the insulation layer IL. The first pixel electrode AE1 may overlap a first pixel area PX1. The second pixel electrode AE2 may overlap a second pixel area PX2. The third pixel electrode AE3 may overlap a third pixel area PX3. Each of the first to third pixel electrodes AE1, AE2 and AE3 may be connected to the driving circuit layer CL through a contact hole passing through the insulation layer IL.

For example, each of the first to third pixel electrodes AE1, AE2 and AE3 may include a metal, an alloy, a metal nitride, a conductive metal oxide, a transparent conductive material, or the like. These materials may be used alone or in combination with each other. In an embodiment of the disclosure, each of the first to third pixel electrodes AE1, AE2 and AE3 may be an anode electrode. Each of the first to third pixel electrodes AE1, AE2 and AE3 may be a reflective electrode.

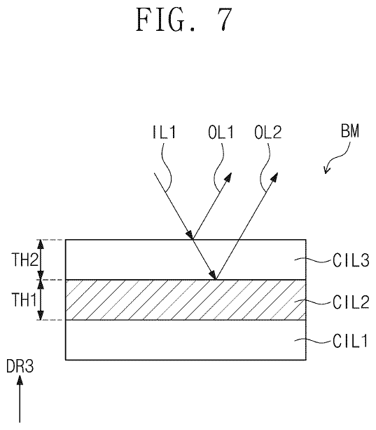

The light emitting layer EL may be disposed on the insulation layer IL and the first to third pixel electrodes AE1, AE2, and AE3. The light emitting layer EL may extend continuously across the first to third pixel areas PX1, PX2 and PX3. For example, the light emitting layer EL may include a hole injection layer, a hole transport layer, an organic light emitting layer, an electron injection layer, an electron transport layer, and the like. In an embodiment of the disclosure, the organic light emitting layer may include a light emitting material that emits white light. For example, the white light may be light in which blue light, green light, and red light may be mixed. Selectively, the white light may be light in which blue light and yellow light may be mixed. A detailed structure of the light emitting layer EL will be described later with reference to FIG. 6.

The common electrode CE may be disposed on the light emitting layer EL. The common electrode CE may extend continuously across the first to third pixel areas PX1, PX2 and PX3. For example, the common electrode CE may include a metal, an alloy, a metal nitride, a conductive metal oxide, a transparent conductive material, or the like. These materials may be used alone or in combination with each other. In an embodiment of the disclosure, the common electrode CE may be a cathode electrode. The common electrode CE may be a transmissive electrode or a transflective electrode.

In the first pixel area PX1, the first pixel electrode AE1, the light emitting layer EL, and the common electrode CE may constitute a first light emitting element. In the second pixel area PX2, the second pixel electrode AE2, the light emitting layer EL, and the common electrode CE may constitute a second light emitting element. In the third pixel area PX3, the third pixel electrode AE3, the light emitting layer EL, and the common electrode CE may constitute a third light emitting element.

The encapsulating layer TFE may be disposed on the common electrode CE. The encapsulating layer TFE may extend continuously across the first to third pixel areas PX1, PX2 and PX3. The encapsulating layer TFE may prevent impurities, moisture, or the like from being introduced into the first to third light emitting elements from the outside. The encapsulating layer TFE may include at least one inorganic layer and at least one organic layer. For example, the inorganic layer may include a silicon oxide, a silicon nitride, a silicon oxynitride, or the like. The inorganic layer of the encapsulating layer TFE may protect the light emitting elements from oxygen and moisture. The organic layer of the encapsulating layer TFE may protect the light emitting elements from dust and impurities. These may be used alone or in combination with each other. The organic layer may include a cured resin such as polyacrylate.

The first to third color filters CF1, CF2 and CF3 may be disposed on the encapsulating layer TFE. The first color filter CF1 may overlap the first pixel area PX1, the second color filter CF2 may overlap the second pixel area PX2, and the third color filter CF3 may overlap the third pixel area PX3. Each of the first to third color filters CF1, CF2 and CF3 may selectively transmit only light having a specific wavelength, and absorb light having the other wavelengths. For example, the first color filter CF1 may transmit red light, the second color filter CF2 may transmit green light, and the third color filter CF3 may transmit blue light. Accordingly, the first pixel area PX1 may emit the red light, the second pixel area PX2 may emit the green light, and the third pixel area PX3 may emit the blue light. However, an embodiment of the disclosure is not limited thereto.

The light blocking pattern BM may be disposed on the encapsulating layer TFE. In a plan view, the light blocking pattern BM may be disposed between the first to third color filters CF1, CF2 and CF3, and not overlap the first to third pixel areas PX1, PX2 and PX3. The light blocking pattern BM may overlap the non-display area NDA.

A thickness THF of the encapsulating layer TFE in the third direction DR3 may be about 3 μm or less. In a case in which the thickness THF of the encapsulating layer TFE is more than about 3 μm, light LA2 emitted obliquely from the light emitting layer EL may reach the second color filter CF2 to cause color mixture of an image of the display module DM. Accordingly, the thickness THF of the encapsulating layer TFE may be decreased to prevent the color mixture of the image of the display module DM. The thickness THF of the encapsulating layer TFE may be about 1.5 μm or less.

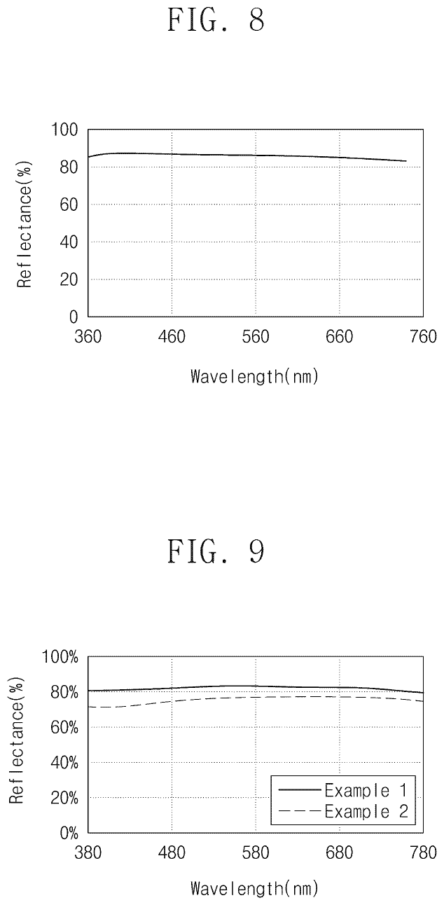

The light blocking pattern BM may block light incident on the light blocking pattern BM. Accordingly, color mixture between the first to third pixel areas PX1, PX2 and PX3 may be prevented. The light blocking pattern BM may include a metal material having a multilayer structure. A reflectance of the light may be about 50% or more. This will be described later with reference to FIG. 7. Here, the reflectance may be a unit that indicates a measure of light reflected from an object in case that the object receives light.

A minimum width WDB of the light blocking pattern BM on a cross-section may be about 5 μm or less. The width WDB of the light blocking pattern BM in the first direction DR1 may be about 5 μm or less. As resolution of the display module DM may increase, a distance between the color filters CF1, CF2 and CF3 may be decreased. Accordingly, a light blocking pattern including an organic material may not be provided between the color filters CF1, CF2 and CF3. In the light blocking pattern BM according to an embodiment of the disclosure, a preliminary light blocking layer including a metal material may be provided and then patterned to provide the light blocking pattern BM. Accordingly, despite a small distance between the color filters CF1, CF2 and CF3, the light blocking pattern BM may be provided between the color filters CF1, CF2 and CF3.

A light transmittance of the light blocking pattern BM may be about 0%. Accordingly, the light LA2 emitted obliquely from the light emitting layer EL may fail to pass through the light blocking pattern BM. Accordingly, the light LA2 emitted obliquely from the light emitting layer EL may be prevented from reaching the color filter CF2 and causing color mixture. Light LA1 emitted from the light emitting layer EL in the third direction DR3 may pass through the first color filter CF1.

The planarization layer PL may be disposed on the color filters CF1, CF2 and CF3 and the light blocking pattern BM. The planarization layer PL may cover the color filters CF1, CF2 and CF3 and the light blocking pattern BM. The planarization layer PL may cover respective upper surfaces, which may be different in height, of the color filters CF1, CF2 and CF3 and the light blocking pattern BM, and have a substantially flat upper surface. For example, the planarization layer PL may include an inorganic material and/or an organic material.

The phase retardation plate QWP may be disposed on the display panel DP. Specifically, the phase retardation plate QWP may be disposed on the color filters CF1, CF2 and CF3, and retard a phase of light passing through the phase retardation plate QWP. The phase retardation plate QWP may be in contact with the display panel DP. For example, the phase retardation plate QWP may be a film type or a liquid crystal coating type. For example, the phase retardation plate QWP may be separately manufactured to be attached to the display panel DP, or may be provided on (e.g., directly on) the display panel DP through a semiconductor lithography tool. In an embodiment of the disclosure, the phase retardation plate QWP may include a λ/4 phase retardation plate. The phase retardation plate QWP may retard a phase of the light incident on the phase retardation plate QWP by about λ/4 .

The wire grid polarizer WGP may be disposed on the phase retardation plate QWP. Specifically, the wire grid polarizer WGP may be in contact with the phase retardation plate QWP. The wire grid polarizer WGP may include multiple metal patterns spaced apart by a distance (e.g., predetermined or selectable distance) from each other. For example, the metal patterns may be spaced apart from each other in the first direction DR1. For example, the wire grid polarizer WGP may be a film type or a liquid crystal coating type. For example, the wire grid polarizer WGP may be separately manufactured to be attached to the display panel DP, or may be provided on (e.g., directly on) the display panel DP through a semiconductor lithography machine.

The metal patterns of the wire grid polarizer WGP may extend to be parallel to each other in a direction (e.g., the second direction DR2). For example, a component of incident light polarized in a direction perpendicular to an extending direction of the wire grid polarizer WGP may pass through the wire grid polarizer WGP. Otherwise, a component of incident light polarized in a direction parallel to the extending direction of the wire grid polarizer WGP may be reflected by the wire grid polarizer WGP. The wire grid polarizer WGP may include a metal having a relatively high reflectance. For example, the wire grid polarizer WGP may include a metal such as aluminum (Al), gold (Au), silver (Ag), copper (Cu), chrome (Cr), iron (Fe), nickel (Ni), or a combination thereof. These metals may be used alone or in combination with each other.

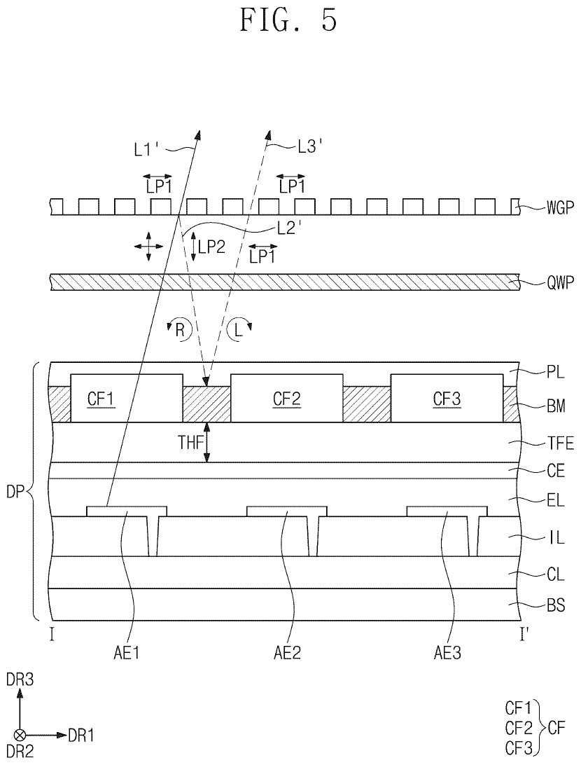

The phase retardation plate QWP may be disposed to be closer to the light blocking pattern BM than the wire grid polarizer WGP. The wire grid polarizer WGP may be disposed to be closer to the cover window CW than the phase retardation plate WGP. The wire grid polarizer WGP may be in contact with an upper surface of the phase retardation plate QWP. Part of light emitted from the light emitting layer EL may be recycled due to the phase retardation plate QWP and the wire grid polarizer WGP. This will be described later with reference to FIG. 4.

The cover window CW may be disposed on the wire grid polarizer WGP. The cover window CW may protect the display panel DP. For example, the cover window CW may include tempered glass, reinforced plastics, or the like. Selectively, the cover window CW may be provided as a single layer, or have a structure in which multiple functional layers may be stacked on each other.

The display module DM according to an embodiment of the disclosure may be a display device that displays an image. For example, the display module DM may be a display device such as an organic light emitting display device, a liquid crystal display device, an organic light emitting diode on silicon substrate (OLEDos), a liquid crystal on silicon substrate (LCos), or a light emitting diode on silicon substrate (LEDos). In an embodiment of the disclosure, the display module DM may be a display device such as OLEDos.

FIG. 4 is a schematic cross-sectional view for explaining recycled light generated in a display module according to an embodiment of the disclosure.

Referring to FIG. 4, part of light emitted from a light emitting layer EL may be recycled due to a phase retardation plate QWP and a wire grid polarizer WGP. First light L1 emitted from the light emitting layer EL may pass through the phase retardation plate QWP. A phase of the first light L1 passing through the phase retardation plate QWP may be retarded by about λ/4. The first light L1 passing through the phase retardation plate QWP may be incident on the wire grid polarizer WGP. First linearly polarized light LP1 of the first light L1 incident on the wire grid polarizer WGP may be transmitted, and second linearly polarized light LP2 of the first light L1 may be reflected. The first linearly polarized light LP1 may correspond to a component of incident light L1 polarized in a direction perpendicular to an extending direction of the wire grid polarizer WGP, and the second linearly polarized light LP2 may correspond to a component of incident light Ll polarized in a direction parallel to the extending direction of the wire grid polarizer WGP. The second linearly polarized light LP2 reflected by the wire grid polarizer WGP may pass through the phase retardation plate QWP to be retarded in phase by about λ/4, thereby being converted into first circularly polarized light R. The first circularly polarized light R may be right-handed circularly polarized light.

The first circularly polarized light R may be incident on a common electrode CE, and reflected from the common electrode CE to be converted into second circularly polarized light L. The second circularly polarized light L may be left-handed circularly polarized light. The second circularly polarized light L may pass through the phase retardation plate QWP to be retarded in phase by about λ/4, thereby being converted into the first linearly polarized light LP1. The first linearly polarized light LP1 may be incident on the wire grid polarizer WGP, and pass through the wire grid polarizer WGP.

As a result, as the phase retardation plate QWP and the wire grid polarizer WGP may be disposed on a display panel DP, the part of the light emitted from the light emitting layer EL may be recycled without being blocked. An absorptive polarizer, which blocks the part of the light emitted from the light emitting layer EL, may not be disposed on the display panel DP. For example, the phase retardation plate QWP and the wire grid polarizer WGP may replace the absorptive polarizer. Accordingly, light efficiency of the display module DM may be improved.

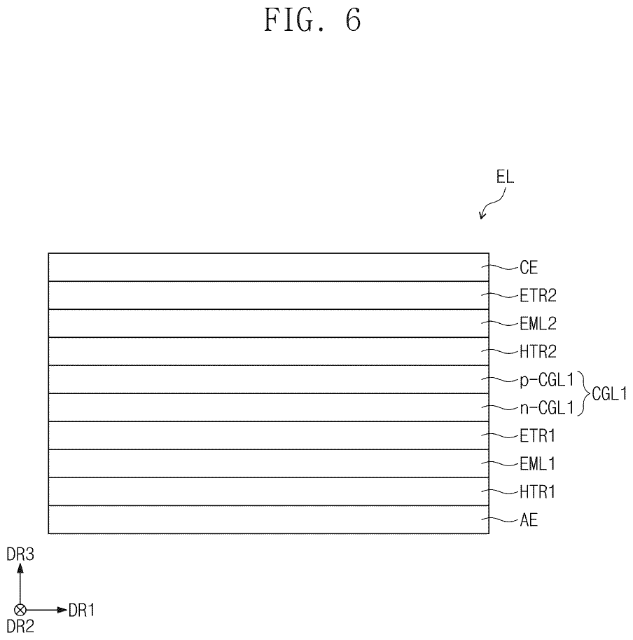

FIG. 5 is a schematic cross-sectional view for explaining recycled light generated in a display module according to an embodiment of the disclosure. Hereinafter, the same/similar components as/to those described with reference to FIGS. 1 to 4 may be designated by the same/similar reference numbers or symbols, and will not be described or will be briefly described.

Referring to FIG. 5, light emitted obliquely from a light emitting layer EL and reflected from a light blocking pattern BM may be recycled. First light L1′ emitted from the light emitting layer EL may pass through a phase retardation plate QWP, and a phase of the first light L1′ may be retarded by about λ/4. The first light L1′ passing through the phase retardation plate QWP may be incident on a wire grid polarizer WGP.

First linearly polarized light LP1 of the first light L1′ incident on the wire grid polarizer WGP may pass through the wire grid polarizer WGP. Second light L2′ that may be part of the first light L1′incident on the wire grid polarizer WGP may be reflected by the wire grid polarizer WGP. Second linearly polarized light LP2 of the second light L2′ may travel toward the phase retardation plate QWP. The first linearly polarized light LP1 may be a component of incident light polarized in a direction perpendicular to an extending direction of the wire grid polarizer WGP, and the second linearly polarized light LP2 may be light polarized in a direction parallel to the extending direction of the wire grid polarizer WGP.

The second linearly polarized light LP2 of the second light L2′ reflected by the wire grid polarizer WGP may pass through the phase retardation plate QWP to be retarded in phase by about λ/4, thereby being converted into first circularly polarized light R. The first circularly polarized light R may be right-handed circularly polarized light.

Part of the first circularly polarized light R may be incident on the light blocking pattern BM, and reflected from the light blocking pattern BM. Third light L3′ reflected may travel toward the phase retardation plate QWP. Here, a reflectance of the light of the light blocking pattern BM may be at least about 50% or more. In a case in which the reflectance of the light of the light blocking pattern BM is less than about 50%, it may not be likely to recycle the light reflected from the light blocking pattern BM to improve the efficiency. For example, the light reflected from the light blocking pattern BM may be less, and thus the light efficiency may not be improved compared to the conventional display module. The reflectance of the light blocking pattern BM may be about 80% or more.

The first circularly polarized light R may be reflected from the light blocking pattern BM to be converted into second circularly polarized light L. The second circularly polarized light R that is the third light L3′ may be left-handed circularly polarized light. The second circularly polarized light L may pass through the phase retardation plate QWP to be retarded in phase by about λ/4, thereby being converted into the first linearly polarized light LP1. The first linearly polarized light LP1 may pass through the wire grid polarizer WGP.

As above, the light emitted obliquely from the light emitting layer EL to be incident between color filters CF1, CF2 and CF3 may be reflected by the light blocking pattern BM to be recycled to increase the light efficiency. Here, the light efficiency may represent an amount of light relative to power consumption. The light reflected from the light blocking pattern BM may pass through the phase retardation plate QWP to be retarded in phase by about λ/4, thereby passing through the wire grid polarizer WGP. Accordingly, the light blocking pattern BM having a high reflectance may reflect the light to recycle part of light that would not be utilized if the light blocking pattern BM were not included or were a light blocking pattern BM including an organic material.

FIG. 6 is a schematic cross-sectional view of a light emitting layer according to an embodiment of the disclosure.

Referring to FIG. 6, a light emitting layer EL according to an embodiment of the disclosure may include a first light emitting layer EML1, a first charge generation layer CGL1, and a second light emitting layer EML2, which are stacked in sequence in the third direction DR3 and disposed between a pixel electrode AE1 and a common electrode CE. The pixel electrode AE shown in FIG. 6 may represent any one of the first to third pixel electrodes AE1, AE2, AE3. FIG. 6 illustrates a tandem light-emitting element as the light emitting layer EL, but a structure of the light emitting layer EL is not limited thereto. The structure of the light emitting layer EL may be changed as desirable.

For example, in FIG. 3, the light emitting layer EL may include a first light emitting layer overlapping the first pixel area PX1, a second light emitting layer overlapping the second pixel area PX2, and a third light emitting layer overlapping the third pixel area PX3. The first to third light emitting layers may emit red light, green light, and blue light, respectively. Each of the first to third light emitting layers may be formed through a separate deposition process.

The pixel electrode AE and the common electrode CE may oppose each other. The first charge generation layer CGLI may be provided between pixel electrode AE and the common electrode CE. The first light emitting layer EML1 may be provided between the pixel electrode AE and the first charge generation layer CGL1. The second light emitting layer EML2 may be provided between the first charge generation layer CGLI and the common electrode CE.

The light emitting layer EL according to an embodiment of the disclosure may be the light emitting layer EL that provides white light. The light emitting layer EL according to an embodiment of the disclosure may be an upper emission type. The pixel electrode AE may be a reflective electrode, and the common electrode CE may be a transmissive electrode or a transflective electrode. In the upper emission type, a high aperture ratio may be secured.

The light emitting layer EL according to an embodiment of the disclosure may be a tandem light-emitting layer EL. As described above, the light emitting layer EL according to an embodiment of the disclosure may include the first charge generation layer CGL1 provided between the pixel electrode AE and the common electrode CE. The light emitting layer EL according to an embodiment of the disclosure has a structure including a first stack, which may include the first light emitting layer EMLI provided below the first charge generation layer CGL1, and a second stack which may include the second light emitting layer EML2 provided above the first charge generation layer CGL1, on the basis of the first charge generation layer CGL1. The first charge generation layer CGLI may be provided on the first stack. The first stack and the second stack may be stacked in sequence in the third direction DR3.

The first charge generation layer CGL1 may serve to inject charges into each of the light emitting layers. The first charge generation layer CGL1 may serve to adjust charge balance between the first stack and the second stack. The first charge generation layer CGL1 may include an n-type charge generation layer n-CGL1 and a p-type charge generation layer p-CGL1. The p-type charge generation layer p-CGL1 may be provided on the n-type charge generation layer n-CGL1.

The first charge generation layer CGL1 may have a structure in which the n-type charge generation layer n-CGL1 and the p-type charge generation layer p-CGL1 may be bonded to each other. The n-type charge generation layer n-CGL1 may be provided to be closer to the pixel electrode AE than the common electrode CE. The p-type charge generation layer p-CGL1 may be provided to be closer to the common electrode CE than the common electrode CE. The n-type charge generation layer n-CGL1 may supply electrons to the first light emitting layer EML1 adjacent to the pixel electrode AE, and the p-type charge generation layer p-CGL1 supplies holes to the second light emitting layer EML2 included in the second stack. A buffer layer (not illustrated) may be further included between the n-type charge generation layer n-CGL1 and the p-type charge generation layer p-CGL1. As the first charge generation layer CGL1 may be provided between the first stack and the second stack to supply charges to each of the light emitting layers, luminance efficiency may increase and a driving voltage may decrease.

The first stack may further include a first hole transport region HTR1 provided between the pixel electrode AE and the first light emitting layer EML1. The first hole transport region HTR1 may include at least one of a hole injection layer or a hole transport layer. The first hole transport region HTR1 may further include at least one of a hole buffer layer or an electron blocking layer.

The first stack may further include a first electron transport region ETR1 provided between the first light emitting layer EML1 and the first charge generation layer CGL1. The first electron transport region ETR1 may include at least one of a hole blocking layer, an electron transport layer, or an electron injection layer, but is not limited thereto.

The second stack may be provided on the first charge generation layer CGL1. The second stack may further include a second hole transport region HTR2 provided between the first charge generation layer CGLI and the second light emitting layer EML2. The foregoing description of the first hole transport region HTR1 may apply to the second hole transport region HTR2. The first hole transport region HTR1 and the second hole transport region HTR2 may be the same or different from each other.

The second stack may further include a second electron transport region ETR2 provided between the second light emitting layer EML2 and the common electrode CE. The foregoing description of the first electron transport region ETR1 may apply to the second electron transport region ETR2, and thus the second electron transport region ETR2 will not be specifically described herein. The first electron transport region ETR1 and the second electron transport region ETR2 may be the same or different from each other.

FIG. 7 is a schematic cross-sectional view of a light blocking pattern according to an embodiment of the disclosure.

Referring to FIG. 7, the light blocking pattern BM may include a metal layer having a multilayer structure. The light blocking pattern BM may include a first metal layer CIL1, a second metal layer CIL2, and a third metal layer CIL3. The first metal layer CIL1, the second metal layer CIL2, and the third metal layer CIL3 may be stacked on each other in sequence. The second metal layer CIL2 may be disposed on the first metal layer CIL1, and the third metal layer CIL3 may be disposed on the second metal layer CIL2.

The second metal layer CIL2 may be disposed between the first metal layer CIL1 and the third metal layer CIL3. Among the first to third metal layers CILI, CIL2 and CIL3, the third metal layer CIL3 may be disposed closest to the phase retardation plate QWP (see FIG. 3) in FIG. 3. Among the first to third metal layers CIL1, CIL2 and CIL3, the first metal layer CIL1 may be disposed closest to the light emitting layer EL (see FIG. 3) in FIG. 3.

A reflectance of the light blocking pattern BM may be about 50% or more. For example, a proportion of a sum of first reflected light OLI which is reflected from a surface of the third metal layer CIL3 of light IL1 incident toward the light blocking pattern BM, and second reflected light OL2 which is reflected from a surface of the second metal layer CIL2 of the light IL1, may be about 50% or more.

A light transmittance of the light blocking pattern BM may be substantially about 0%. For example, the light IL1 incident toward the light blocking pattern BM may not pass through the light blocking pattern BM. As the light blocking pattern BM may be disposed between the color filters CF1, CF2 and CF3 (see FIG. 3), in case that the light transmittance is about 0%, color mixture between the color filters CF1, CF2 and CF3 (see FIG. 3) may be prevented.

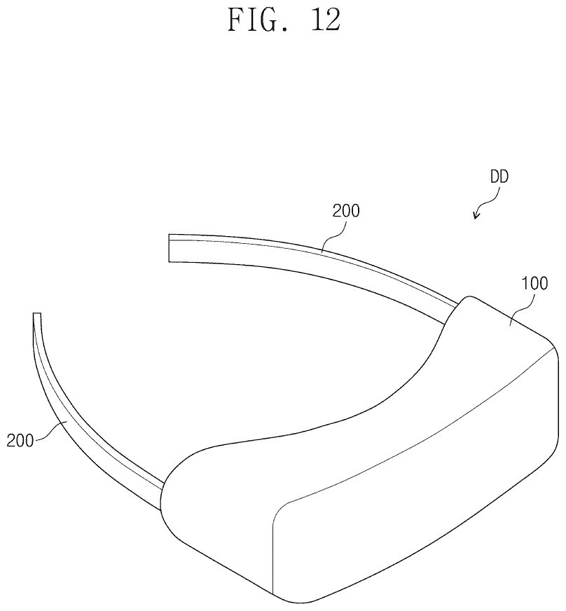

The third metal layer CIL3 may be disposed on (e.g., directly on) the second metal layer CIL2. A thickness TH2 of the third metal layer CIL3 in the third direction DR3 may be about 150 angstroms (or Å) or less. As the thickness TH2 of the third metal layer CIL3 decreases, the reflectance of the light blocking pattern BM increases. Thus, in case that the thickness TH2 of the third metal layer CIL3 is more than about 150 angstroms (Å), the reflectance of the light blocking pattern BM may be decreased to less than about 50%, and thus an effect of increasing the light efficiency may be insignificant. This will be described later with reference to FIG. 10.

The third metal layer CIL3 may include titanium. When patterning the light blocking pattern BM, the third metal layer CIL3 may prevent the second metal layer CIL2 from being corroded. However, as the third metal layer CIL3 may reduce the reflectance of the light blocking pattern BM, the third metal layer CIL3 having a minimum thickness may be used.

The second metal layer CIL2 may be disposed between the first metal layer CIL1 and the third metal layer CIL3. The second metal layer CIL2 may include aluminum. A thickness TH1 of the second metal layer CIL2 in the third direction DR3 may be about 1000 angstroms (Å) or more. In a case in which the thickness TH1 of the second metal layer CIL2 is less than about 1000 angstroms (Å), the light transmittance of the light blocking pattern BM may not be substantially about 0%, and the reflectance of the light blocking pattern BM may be less than about 50%. The second metal layer CIL2 may have the thickness THI of about 1500 angstroms (Å) to about 2000 angstroms (Å).

A light transmittance of the second metal layer CIL2 may be substantially about 0%. As the thickness THI of the second metal layer CIL2 may be about 1000 angstroms (Å) or more, light may not pass through the second metal layer CIL2. Accordingly, color mixture of the display module DM (see FIG. 3) may be prevented.

A reflectance of the second metal layer CIL2 may be about 80% or more. The second metal layer CIL2 may be a main component for recycling light. Thus, a high reflectance may be required. In a case in which the reflectance of the second metal layer CIL2 is less than about 80%, the reflectance of the light blocking pattern BM may be decreased to less than about 50%. Accordingly, the effect of increasing the light efficiency of the display module DM (see FIG. 3) according to an embodiment of the disclosure may be insignificant.

The first metal layer CILI may include at least one of titanium, molybdenum, or molybdenum-tantalum oxide (MoTaO). The first metal layer CIL1 may be disposed on (e.g., directly on) a lower surface of the second metal layer CIL2. The first metal layer CILI may improve adhesion between the second metal layer CIL2 and the encapsulating layer TFE (see FIG. 3).

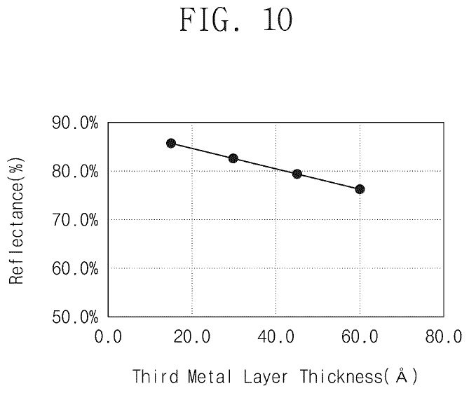

FIG. 8 is a graph illustrating reflectance over wavelength for a wire grid polarizer according to an embodiment of the disclosure.

Referring to FIGS. 3 and 8, the wire grid polarizer WGP (see FIG. 3) may have a reflectance that may be constantly high regardless of wavelengths. For example, about 85% of light incident toward the wire grid polarizer WGP may be reflected. Thus, recycling the light reflected by the wire grid polarizer WGP is desirable for an increase in luminous efficiency of the display module DM.

Table 1 below shows light efficiency increase ratios according to an embodiment of the disclosure and a Comparative Example.

In Examples 1 to 3, titanium having a thickness of about 600 angstroms (Å) was used as the first metal layer CILI (see FIG. 7), aluminum having a thickness of about 2000 angstroms (Å) was used as the second metal layer CIL2 (see FIG. 7), and titanium was used as the third metal layer CIL3 (see FIG. 7). Example 1 is a case in which a thickness of the third metal layer CIL3 (see FIG. 7) is about 30 angstroms (Å), Example 2 is a case in which the thickness of the third metal layer CIL3 (see FIG. 7) is about 50 angstroms (Å), and Example 3 may be a case in which the thickness of the third metal layer CIL3 (see FIG. 7) may be about 60 angstroms (Å).

The Comparative Example is a case in which a light blocking pattern including an organic material was used. A light efficiency ratio represents how much the light efficiency is increased in case that the light blocking pattern is applied, based on an assumption that a light efficiency ratio of a case without the light blocking pattern is about 100%.

TABLE 1

| | Exam- | Exam- | Exam- | Comparative |
|---|---|---|---|---|
| | ple 1 | ple 2 | ple 3 | Example |
| Reflectance of light blocking | 83% | 78% | 76% | 4.5% |
| pattern (BM) | | | | |
| Light efficiency ratio (white) | 143% | 138.1% | 136.7% | 114.8% |
| Light efficiency ratio (red) | 142.7% | 140.3% | 142.4% | 113.7% |
| Light efficiency ratio (green) | 144.3% | 139.1% | 135.9% | 114.2% |
| Light efficiency ratio (blue) | 140.0% | 135.7% | 134.9% | 113.8% |

Referring to FIG. 3 and Table 1, it may be confirmed that the reflectances of the cases (Examples 1, 2 and 3), in which a metal material having a multilayer structure including titanium/aluminum/titanium is used as the light blocking pattern BM, are about 83%, about 78%, and about 76%, respectively, each of which is higher than about 4.5% that is the reflectance of the case (Comparative Example) in which an organic material is used as the light blocking pattern BM. In terms of the light efficiency ratio, it may be confirmed that each of Examples 1 to 3 has the higher light efficiency ratio than Comparative Example in all of the cases of the red light, the blue light, the green light, and the white light. In Examples 1, 2 and 3, the reflectance of the light blocking pattern BM is high, and thus the amount of the recycled light may be large to lead an increase in light efficiency ratio.

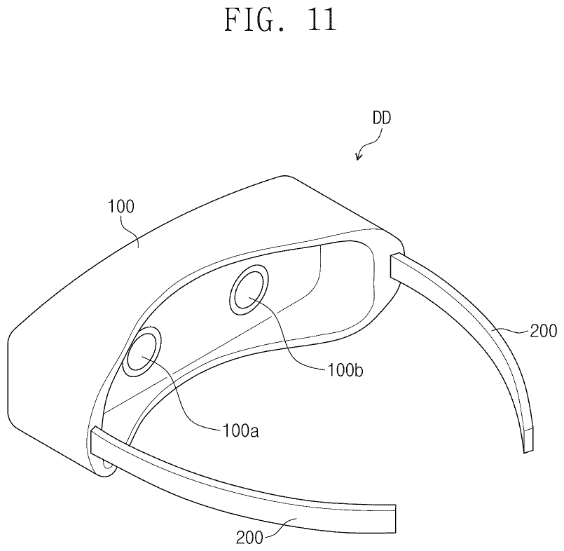

In case that the light efficiency ratio (white) is examined, the Comparative Example has the value of about 114.8%, but Examples 1, 2 and 3 according to an embodiment of the disclosure have the higher values of about 143%, about 138.1%, and about 136.7%, respectively. When Examples 1, 2 and 3 are compared with each other, Example 1 in which the third metal layer CIL3 (see FIG. 7) has the smallest thickness had the light efficiency ratio of about 143%, which is the highest. Example 3 in which the third metal layer CIL3 (see FIG. 7) has the largest thickness had the light efficiency ratio of about 136.7%, which is the lowest. For example, it may be ascertained that as the thickness of the third metal layer CIL3 (see FIG. 7) decreases, the light efficiency ratio increases. As described later with reference to FIG. 9, this is because as the thickness of the third metal layer CIL3 (see FIG. 7) decreases, the reflectance of the light blocking pattern BM (see FIG. 7) increases.

Exceptionally in the red light, the light efficiency ratio of Example 2 is about 140.3%, and the light efficiency ratio of Example 3 is about 142.4%, which shows that even though the third metal layer CIL3 (see FIG. 7) according to Example 3 has the larger thickness, Example 3 exhibits the higher light efficiency ratio than Example 2. However, Example 1, in which the third metal layer CIL3 (see FIG. 7) has a smaller thickness than each of Examples 2 and 3 exhibits the light efficiency ratio of about 142.7% that is a value more than each of the values of Examples 2 and 3.

Except the case of the red light, the light efficiency ratios in the cases of the green light and the blue light each show a similar tendency to the light efficiency ratio in the case of the white light. For example, Example 1 in which the third metal layer CIL3 (see FIG. 7) has the smallest thickness exhibits the highest light efficiency ratio, and Example 3 in which the third metal layer CIL3 (see FIG. 7) has the largest thickness exhibits the lowest light efficiency ratio. Considering the results in Table 1, it may be confirmed that as the thickness of the third metal layer CIL3 (see FIG. 7) of the light blocking pattern BM is decreased, the light efficiency ratio is increased.

FIG. 9 is a graph illustrating reflectance over wavelength for a light blocking pattern according to an embodiment of the disclosure.

Referring to FIG. 9, line 1 shows reflectance over wavelength for Example 1described above, and line 2 shows reflectance over wavelength for Example 2 described above. Examples 1 and 2 are different in that the thicknesses of the third metal layers CIL3 (see FIG. 7) thereof are about 30 angstroms (Å) and about 50 angstroms (Å), respectively. In Example 1 in which the third metal layer CIL3 (see FIG. 7) has the smallest thickness, the reflectance was about 80% or more over the entire visible wavelength spectrum, and higher than the reflectance of Example 2.

FIG. 10 is a graph illustrating reflectance over thickness for a third metal layer according to an embodiment of the disclosure.

Referring to FIG. 10, the reflectance of the light blocking pattern BM (see FIG. 7) over the thickness of the third metal layer CIL3 (see FIG. 7) is shown. It may be confirmed that in general, as the thickness of the third metal layer CIL3 (see FIG. 7) decreases, the

In a case in which the thickness of the third metal layer CIL3 (see FIG. 7) is about 15 angstroms (Å), the reflectance of the light blocking pattern BM (see FIG. 7) may be about 86%. In a case in which the thickness of the third metal layer CIL3 (see FIG. 7) is about 30 angstroms (Å), the reflectance of the light blocking pattern BM (see FIG. 7) may be about 82%. In a case in which the thickness of the third metal layer CIL3 (see FIG. 7) is about 45 angstroms (Å), the reflectance of the light blocking pattern BM (see FIG. 7) may be about 78%. In a case in which the thickness of the third metal layer CIL3 (see FIG. 7) is about 60 angstroms (Å), the reflectance of the light blocking pattern BM (see FIG. 7) may be about 74%. The thickness of the third metal layer CIL3 (see FIG. 7) and the reflectance of the light blocking pattern BM (see FIG. 7) may have an inverse relationship with each other.

Although not illustrated in FIG. 10, in a case in which the thickness of the third metal layer CIL3 (see FIG. 7) is about 150 angstroms (Å), the reflectance of the light blocking pattern BM (see FIG. 7) may be about 50%. In a case in which the reflectance of the light blocking pattern BM (see FIG. 7) is less than about 50%, a light efficiency-improving effect of the display module (see FIG. 7) may be insignificant. Thus, the thickness of the third metal layer CIL3 (see FIG. 7) may be about 150 angstroms (Å) or less.

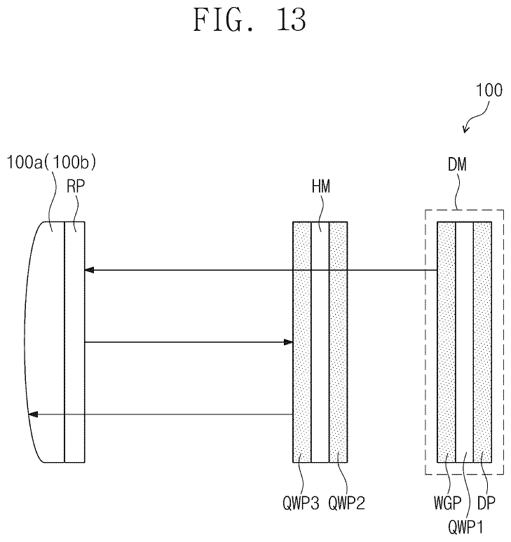

FIGS. 11 and 12 are schematic plan views illustrating a display device according to an embodiment of the disclosure.

Referring to FIGS. 11 and 12, a display device DD according to an embodiment of the disclosure may include a display module accommodation part 100, a first ocular lens 100a, a second ocular lens 100b, and a glasses temple 200. For example, the display device DD according to an embodiment of the disclosure may be embodied as a head mounted display. Thus, hereinafter, the head mounted display will be described as an example of the display device DD.

The display module accommodation part 100 may include a display module which displays an image, and optical members for providing the first and second ocular lenses 100a and 100b with the image displayed on the display module. Here, the display module may correspond to the display module DM illustrated in FIGS. 1 and 3 to 5. The display module accommodation part 100 will be specifically described later.

The first and second ocular lenses 100a and 100b may be disposed in a surface (e.g., single surface) of the display module accommodation part 100. Specifically, the first and second ocular lenses 100a and 100b may be disposed in a lower surface of the display module accommodation part 100. For example, the first ocular lens 100a may be a left-eye lens at which a left eye of a user may be positioned, and the second ocular lens 100b may be a right-eye lens at which a right eye of the user may be positioned. The user may view an image displayed by the display module of the display module accommodation part 100 through the first and second ocular lenses 100a and 100b.

The display device DD may provide the user with the image displayed on the display module of the display module accommodation part 100 through the first and second ocular lenses 100a and 100b. As a result, the display device DD may provide the user with a virtual image displayed by the display module of the display module accommodation part 100. For example, the display device DD may realize virtual reality (VR).

The glasses temple 200 may be a component that allows the user to readily wear or take off. However, an embodiment of the disclosure is not limited thereto, and the display device DD may include a head mounted band capable of being mounted on a head instead of the glasses temple 200.

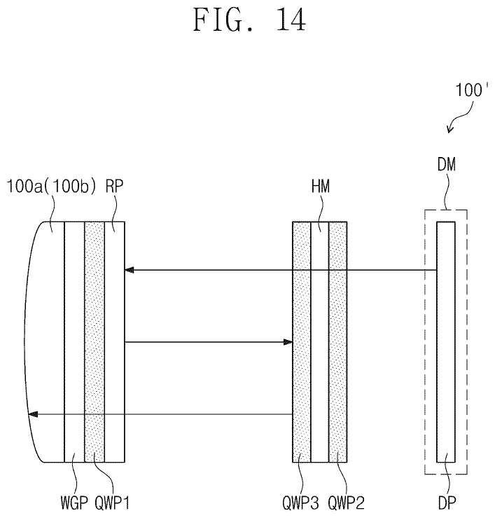

FIGS. 13 and 14 are side views of a display module accommodation part according to an embodiment of the disclosure.

FIG. 13 is a side view illustrating an example of a display module accommodation part of an electronic apparatus in FIGS. 11 and 12. FIG. 14 is a side view illustrating an example of a display module accommodation part of an electronic apparatus in FIGS. 11 and 12. For example, FIGS. 13 and 14 illustrate components of a display module accommodation part 100 for providing an image to the first and second ocular lenses 100a and 100b of the display device DD in FIGS. 11 and 12.

Referring to FIGS. 13 and 14, the display module accommodation part 100 of the display device DD according to an embodiment of the disclosure may include a display panel DP, a first phase retardation plate QWP1, a wire grid polarizer WGP, a second phase retardation plate QWP2, a half mirror HM, a third phase retardation plate QWP3, and a reflective polarizer RP.

The wire grid polarizer WGP may be disposed between the display panel DP and the ocular lenses 100a and 100b. The first phase retardation plate QWP1 may be disposed between the wire grid polarizer WGP and the display panel DP, and be adjacent to the wire grid polarizer WGP. The first phase retardation plate QWP1 and the wire grid polarizer WGP which are illustrated in FIGS. 13 and 14 may correspond to the phase retardation plate QWP and the wire grid polarizer WGP, respectively, which are illustrated in FIGS. 3 to 5.

In an embodiment of the disclosure, as illustrated in FIG. 13, the first phase retardation plate QWP1 may be in contact with a surface (e.g., single surface) of the display panel DP, the wire grid polarizer WGP may be in contact with a surface (e.g., single surface) of the first phase retardation plate QWP1, and the reflective polarizer RP may be in contact with a surface (e.g., single surface) of the ocular lenses 100a and 100b. The display panel DP, the first phase retardation plate QWP1, the wire grid polarizer WGP, and a cover window (e.g., the cover window CW in FIG. 3) may constitute a display module DM, and the display module DM may may correspond to the display module DM illustrated in FIG. 3.

In an embodiment of the disclosure, as illustrated in FIG. 14, the wire grid polarizer WGP may be in contact with the another surface of the ocular lenses 100a and 100b, and the first phase retardation plate QWP1 may be disposed between the wire grid polarizer WGP and the reflective polarizer RP. Specifically, a surface (e.g., single surface) of the first phase retardation plate QWP1 may be in contact with the wire grid polarizer WGP and another surface of the first phase retardation plate QWP1 may be in contact with the reflective polarizer RP. The display panel DP and the cover window may constitute the display module DM, and the display module DM may not include the first phase retardation plate QWP1 and the wire grid polarizer WGP.

The second phase retardation plate QWP2 may be disposed between the display panel DP and the ocular lenses 100a and 100b. Specifically, the second phase retardation plate QWP2 may be in contact with a surface (e.g., single surface) of the half mirror HM. In an embodiment of the disclosure, the second phase retardation plate QWP2 may include a λ/4 phase retardation plate. The second phase retardation plate QWP2 may retard a phase of incident light about λ/4.

The half mirror HM may be disposed between the second phase retardation plate QWP2 and the third phase retardation plate QWP3. Specifically, a surface (e.g., single surface) of the half mirror HM may be in contact with the second phase retardation plate QWP2, and another surface of the half mirror HM may be in contact with the third phase retardation plate QWP3.

The half mirror HM may include a transflector that transmits part of light and reflects other part of the light. For example, the half mirror HM may include glass having a surface (e.g., single surface) on which a transflective metal film may be provided. For example, the transflective metal film may include a transflective metal material such as magnesium (Mg), silver (Ag), an alloy containing magnesium (Mg) and silver (Ag), or a combination thereof. These materials may be used alone or in combination with each other.

The third phase retardation plate QWP3 may be in contact with another surface of the half mirror HM. In an embodiment of the disclosure, the third phase retardation plate QWP3 may include a λ/4 phase retardation plate. The third phase retardation plate QWP3 may retard a phase of incident light by about λ/4.

The reflective polarizer RP may be disposed between the ocular lenses 100a and 100b and the second phase retardation plate QWP2. Specifically, the reflective polarizer RP may be disposed between the ocular lenses 100a and 100b and the third phase retardation plate QWP3. The reflective polarizer RP may transmit first linearly polarized light that vertically vibrates (or is polarized in a vertical direction), and reflect second linearly polarized light that horizontally vibrates (or that is polarized in a horizontal direction. For example, the reflective polarizer RP may be an advanced polarizing film (APF) or a dual bright enhanced film (DBEF). However, an embodiment of the disclosure is not limited thereto.

The ocular lenses 100a and 100b may be convex lenses or Fresnel lenses. As a polarizer (e.g., the reflective polarizer RP) or the wire grid polarizer WGP may be in contact with the a surface (e.g., single surface) of the ocular lenses 100a and 100b, the a surface (e.g., single surface) of the ocular lenses 100a and 100b may be provided to be substantially flat to readily come into contact with the polarizer. A convex lens or Fresnel lens may be provided in another surface of the ocular lenses 100a and 100b.

As the display module accommodation part 100 may include the components as above, an image may be provided for a user through the ocular lenses 100a and 100b. For example, part of light emitted from the display module DM may pass through the second phase retardation plate QWP2, the half mirror HM, and the third phase retardation plate QWP3, and then be incident on the reflective polarizer RP. Part of the light incident on the reflective polarizer RP may be reflected to be incident on the half mirror HM. Part of the light incident on the half mirror HM may be reflected to be incident on the ocular lenses 100a and 100b. Accordingly, an image displayed on the display module DM may be provided for a user.

In the display device DD according to the embodiment of the disclosure, the high-resolution display device DD in which instead of using an organic light blocking pattern, a metal material having the multilayer structure is instead used, and the light blocking pattern BM having the light reflectance of about 50% or more may be provided. Accordingly, the light reflected by the wire grid polarizer WGP may be reflected again to improve the light efficiency.

Moreover, as the light transmittance of the light blocking pattern BM may be about 0%, color mixture may be prevented.

Although the embodiments of the disclosure have been described, it is understood that the disclosure should not be limited to these embodiments of the disclosure but various changes and modifications can be made by one ordinary skilled in the art within the spirit and scope of the disclosure as hereinafter claimed. Therefore, the technical scope of the disclosure is not limited to the contents described in the detailed description of the specification, but should be determined by the claims.

What is claimed is:

1. A display module comprising:
a substrate comprising a plurality of pixel areas;
a driving circuit layer disposed on the substrate;
a light emitting layer disposed on the driving circuit layer and extending continuously across the pixel areas;
a plurality of color filters disposed on the light emitting layer and overlapping the plurality of pixel areas, respectively;
a light blocking pattern disposed between the plurality of color filters and comprising a metal material having a multilayer structure;
a phase retardation plate disposed on the plurality of color filters to retard a phase of incident light; and
a wire grid polarizer disposed on the phase retardation plate and comprising a plurality of metal patterns spaced apart from each other by a distance from each other.

2. The display module of claim 1, wherein the light blocking pattern comprises:
a first metal layer;
a second metal layer disposed on the first metal layer; and
a third metal layer disposed on the second metal layer.

3. The display module of claim 2, wherein among the first, second, and third metal layers, the third metal layer is disposed closest to the phase retardation plate, and
a thickness of the third metal layer is about 150 angstroms or less.

4. The display module of claim 2, wherein a thickness of the second metal layer is about 1000 angstroms or more.

5. The display module of claim 2, wherein a reflectance of the second metal layer is about 80% or more.

6. The display module of claim 2, wherein a light transmittance of the second metal layer is about 0%.

7. The display module of claim 2, wherein the first metal layer comprises at least one of titanium, molybdenum, or molybdenum-tantalum oxide (MoTaO).

8. The display module of claim 2, wherein the second metal layer comprises aluminum.

9. The display module of claim 2, wherein the third metal layer comprises titanium.

10. The display module of claim 1, wherein the phase retardation plate comprises a λ/4 phase retardation plate.

11. The display module of claim 1, wherein the light emitting layer comprises a light emitting material that emits white light.

12. The display module of claim 1, further comprising a cover window disposed on the wire grid polarizer.

13. The display module of claim 1, further comprising:
a planarization layer that covers the plurality of color filters and the light blocking pattern,
wherein the planarization layer comprises a substantially flat upper surface.

14. The display module of claim 1, wherein the phase retardation plate is disposed closer to the light blocking pattern than the wire grid polarizer.

15. The display module of claim 1, wherein a minimum width of the light blocking pattern on a cross-section is about 5 micrometers or less.

16. A display device comprising:
an ocular lens; and
a display module accommodation part that provides an image to the ocular lens;
wherein the display module accommodation part comprises:
a substrate comprising a plurality of pixel areas;
a driving circuit layer disposed on the substrate;
a light emitting layer disposed on the driving circuit layer and extending continuously across the plurality of pixel areas;
a plurality of color filters disposed on the light emitting layer, and overlapping the plurality of pixel areas, respectively;
a light blocking pattern disposed between the plurality of color filters and comprising a metal material;
a phase retardation plate disposed on the plurality of color filters to retard a phase of incident light; and
a wire grid polarizer disposed on the phase retardation plate and comprising a plurality of metal patterns spaced apart from each other by a distance from each other.

17. The display device of claim 16, wherein the light blocking pattern comprises:
a first metal layer;
a second metal layer disposed on the first metal layer; and
a third metal layer disposed on the second metal layer.

18. The display device of claim 17, wherein
among the first, second, and third metal layers, the third metal layer is disposed closest to the phase retardation plate, and
a thickness of the third metal layer is about 150 angstroms or less.

19. The display device of claim 17, wherein a reflectance of the second metal layer is about 80% or more.

20. The display device of claim 17, wherein a light transmittance of the second metal layer is about 0%.
